(19) United States
(12) Patent Application Publication
(10) Pub. No.: US 2019/0348516 A1
(43) Pub. Date: Nov. 14, 2019

(54) WORK FUNCTION MATERIAL RECESS FOR THRESHOLD VOLTAGE TUNING IN FINFETS

(71) Applicant: Intel Corporation, Santa Clara, CA (US)

(72) Inventors: Rahul Ramaswamy, Portland, OR (US); Walid M. Hafez, Portland, OR (US); Roman W. Olac-vaw, Hillboro, OR (US)

(73) Assignee: Intel Corporation, Santa Clara, CA (US)

(21) Appl. No.: 15/973,906

(22) Filed: May 8, 2018

(51) Int. Cl. H01L 29/423; H01L 27/088; H01L 21/8234

(52) U.S. Cl. CPC H01L 29/42376; H01L 27/0886; H01L 21/823456; H01L 21/823431; H01L 29/4236

(57) ABSTRACT

Disclosed herein are transistor arrangements with one or more FinFETs, where threshold voltage tuning of a given FinFET may be implemented by controlling the height of a work function (WF) material provided as a layer at least partially surrounding sidewalls of the upper-most portion of the fin of that FinFET. In some embodiments, such a control may be achieved as a part of forming a gate stack of a FinFET. In particular, a layer of a desired WF material may be deposited within an opening formed around a channel region of a fin as a part of forming the gate stack, and subsequently recessed to a desired height, where, for a given geometry and materials selection, the amount of WF material recess controls threshold voltage of the resulting FinFET. In this manner, different FinFETs in a single transistor arrangement may have different heights of their WF material layer.

### TECHNICAL FIELD

This disclosure relates generally to the field of semiconductor devices, and more specifically, to tuning threshold voltage in transistor devices/arrangements.

### BACKGROUND

Transistors can have planar or non-planar architecture. The term “FinFET” is used to describe a metal oxide semiconductor (MOS) field-effect transistor (FET) with a non-planar architecture in which a fin, formed of one or more semiconductor materials, extends away from a base. Recently, FinFETs have been extensively explored as alternatives to transistors with planar architectures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a perspective view of an exemplary FinFET, according to some embodiments of the disclosure.

FIG. 2 is a cross-sectional side view of an exemplary transistor arrangement with multiple FinFETs implementing work function (WF) material recess for threshold voltage tuning, according to some embodiments of the disclosure.

FIG. 3 is a flow diagram of an exemplary method of manufacturing a transistor arrangement with one or more FinFETs using WF material recess for threshold voltage tuning, according to some embodiments of the disclosure.

FIGS. 4A-4H are cross-sectional side views of an exemplary transistor arrangement, illustrating various example stages in the manufacture of a transistor arrangement with one or more FinFETs using WF material recess for threshold voltage tuning, according to some embodiments of the disclosure.

FIGS. 5A-5B are top views of a wafer and dies that may include one or more transistor arrangements implementing WF material recess to control threshold voltage of one or more FinFETs in accordance with any of the embodiments disclosed herein.

FIG. 6 is a cross-sectional side view of an integrated circuit (IC) device that may include one or more transistor arrangements implementing WF material recess to control threshold voltage of one or more FinFETs in accordance with any of the embodiments disclosed herein.

FIG. 7 is a cross-sectional side view of an IC device assembly that may include one or more transistor arrangements implementing WF material recess to control threshold voltage of one or more FinFETs in accordance with any of the embodiments disclosed herein.

FIG. 8 is a block diagram of an example computing device that may include one or more transistor arrangements implementing WF material recess to control threshold voltage of one or more FinFETs in accordance with any of the embodiments disclosed herein.

### DETAILED DESCRIPTION

### Overview

For purposes of illustrating transistor arrangements implementing WF material recess to control threshold voltage as proposed herein, it is important to understand phenomena that may come into play in a typical transistor. The following foundational information may be viewed as a basis from which the present disclosure may be properly explained. Such information is offered for purposes of explanation only and, accordingly, should not be construed in any way to limit the broad scope of the present disclosure and its potential applications.

Performance of a transistor may depend on the number of factors. Threshold voltage, commonly abbreviated as Vth, refers to the minimum gate-to-source voltage that is needed to create a conducting path between source and drain terminals of a transistor. “Threshold voltage tuning” refers to adapting the threshold voltage of a transistor to a desired value.

Threshold voltage tuning in FinFETs is not trivial. Some approaches to threshold voltage tuning in FinFETs include implant doping or stacking various types of WF materials, typically various metals, on top of the fins. Such approaches present many challenges, such as necessity to use multiple WF metals to achieve the desired threshold voltage, complicated lithography steps, and stringent requirements with respect to accurate control of WF metal deposition process on top of the fin and across a wafer.

Disclosed herein are transistor arrangements with one or more FinFETs, where threshold voltage tuning of a given FinFET, for one or more of the FinFETs present within a transistor arrangement, may be implemented by controlling the height of a WF material provided as a layer at least partially surrounding sidewalls of an upper portion (in particular, the upper-most portion) of the fin of that FinFET. Namely, the height of the WF material layer controls the amount of gate fill material forming most of the gate electrode of a FinFET, which, in turn, controls the threshold voltage. In some embodiments, such a control may be achieved as a part of forming a gate stack of a FinFET. In particular, a layer of a desired WF material may be deposited within an opening formed around a channel region of a fin as a part of forming the gate stack, and subsequently recessed to a desired height, where, for a given geometry and materials selection, the amount of WF material recess controls threshold voltage of the resulting FinFET. In this manner, in some embodiments, different FinFETs in a single transistor arrangement may have different heights of their WF layer, depending on the desired threshold voltages for each of them. Implementing WF material recess for threshold voltage tuning in FinFETs may advantageously reduce the number of WF materials employed to control threshold voltage, and/or reduce the number/complexity of lithographic steps used, compared to some other approached to threshold voltage tuning in FinFETs.

As used herein, the term “WF material” refers to any material that may be used for controlling threshold voltage of a FinFET by controlling the height of that material provided as a layer around the upper-most portion of the fin (e.g. covering the fin). The term “WF material” is used to indicate that it is the WF of the material (i.e. the physical property of the material specifying the minimum thermodynamic work (i.e. energy) needed to remove an electron from a solid to a point in the vacuum immediately outside the solid surface) that may affect the threshold voltage of the final FinFET. Further, as used herein, the term “height” in context of a “height of a WF material” refers to the extent, or dimension, of the WF material a measured in a direction substantially perpendicular to the substrate on which a FinFET is built, or, stated differently, substantially perpendicular to the base of a FinFET.

Various transistor arrangements implementing WF material recess to control threshold voltage as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC, provided as an integral part of an IC, or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which are shown, by way of illustration, embodiments that may be practiced. The accompanying drawings are not necessarily drawn to scale. For example, to clarify various layers, structures, and regions, the thickness of some layers may be enlarged. Furthermore, while drawings illustrating various structures/assemblies of exemplary devices may be drawn with precise right angles and straight lines, real world process limitations may prevent implementations of devices exactly as shown. Therefore, it is understood that such drawings revised to reflect example real world process limitations, in that the features may not have precise right angles and straight lines, are within the scope of the present disclosure. Drawings revised in this manner may be more representative of real world structure/assemblies as may be seen on images using various characterization tools, such as e.g. scanning electron microscopy (SEM) or transmission electron microscopy (TEM). In addition, the various structures/assemblies of the present drawings may further include possible processing defects, such as e.g. the rounding of corners, the drooping of the layers/lines, unintentional gaps and/or discontinuities, unintentionally uneven surfaces and volumes, etc., although these possible processing defects may not be specifically shown in the drawings. It is to be understood that other embodiments may be utilized and structural or logical changes to the drawings and descriptions may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. Furthermore, stating in the present disclosure that any part (e.g. a layer, film, area, or plate) is in any way positioned on or over (e.g. positioned on/over, provided on/over, located on/over, disposed on/over, formed on/over, etc.) another part means that the referenced part is either in contact with the other part, or that the referenced part is above the other part with one or more intermediate part(s) located therebetween. On the other hand, stating that any part is in contact with another part means that there is no intermediate part between the two parts.

The terms “substantially,” “close,” “approximately,” “near,” and “about,” generally refer to being within +/−20% of a target value. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. In some examples, as used herein, a “high-k dielectric” refers to a material having a higher dielectric constant than silicon oxide, while the terms “oxide,” “carbide,” “nitride,” etc. refer to compounds containing, respectively, oxygen, carbon, nitrogen, etc. In another example, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function.

### Exemplary FinFET

FinFETs refer to transistors having a non-planar architecture where a fin, formed of one or more semiconductor materials, extends away from a base. A portion of the fin that is closest to the base may be enclosed by a transistor dielectric material. Such a dielectric material, typically an oxide, is commonly referred to as a “shallow trench isolation” (STI), and the portion of the fin enclosed by the STI is typically referred to as a “subfin portion” or simply a “subfin.” A gate stack that includes at least a layer of a gate electrode metal and a layer of a gate dielectric may be provided over the top and sides of the remaining upper portion of the fin (i.e. the portion above and not enclosed by the STI), thus wrapping around the upper-most portion of the fin. The portion of the fin over which the gate stack wraps around is referred to as a “channel portion” of the fin and is a part of an active region of the fin. A source region and a drain region are provided on either side of the gate stack, forming, respectively, a source and a drain of a transistor.

FinFETs may be implemented as “tri-gate transistors,” where the name “tri-gate” originates from the fact that, in use, such a transistor may form conducting channels on three “sides” of the fin. FinFETs potentially improve performance relative to single-gate transistors and double-gate transistors.

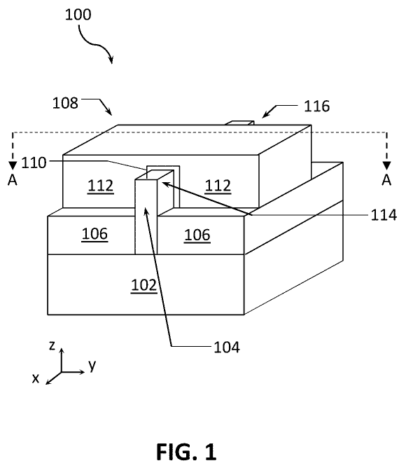

FIG. 1 is a perspective view of an exemplary FinFET 100 in which WF material recess may be used to control the threshold voltage of the FinFET 100, according to some embodiments of the disclosure. Note that the FinFET 100 shown in FIG. 1 is intended to show relative arrangement(s) of some of the components therein, and that the FinFET 100, or portions thereof, may include other components that are not illustrated (e.g., any further materials, such as e.g. spacer materials, surrounding the gate stack of the FinFET 100; electrical contacts to the source and the drain of the FinFET 100; etc.).

As shown, the FinFET 100 may include a base 102, a fin 104, a transistor dielectric material 106 enclosing the subfin portion of the fin 104, and a gate stack 108 that includes a gate dielectric 110 (which could include a stack of one or more gate dielectric materials) and a gate electrode material 112 (which could include a stack of one or more gate electrode materials). Although not specifically shown in FIG. 1 in order to not clutter the drawing, the FinFET 100 may further include a WF material provided as a layer at least partially surrounding sidewalls of an upper portion (in particular, the upper-most portion) of the fin 104. Such a WF material may be viewed as a part of the gate stack 108 of the FinFET 100. FIG. 1 further indicates source/drain (S/D) regions (also commonly referred to as “diffusion regions”) 114 and 116 of the FinFET 100.

In general, implementations of the present disclosure may be formed or carried out on a substrate, such as a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which a semiconductor device implementing any of the FinFETs as described herein may be built falls within the spirit and scope of the present disclosure. In various embodiments the base 102 may include any such substrate material that provides a suitable surface for forming the FinFET 100.

As shown in FIG. 1, the fin 104 extends away from the base 102 and is substantially perpendicular to the base 102. The fin 104 may include one or more semiconductor materials, e.g. a stack of semiconductor materials, so that the upper-most portion of the fin (namely, the portion of the fin 104 enclosed by the gate stack 108) may serve as the channel region of the FinFET 100.

The transistor dielectric material 106 forms an STI enclosing the sides of the fin 104. A portion of the fin 104 enclosed by the STI 106 forms a subfin. In various embodiments, the STI material 106 may be a low-k or high-k dielectric including but not limited to elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used in the STI material 106 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

Above the subfin portion of the fin 104, the gate stack 108 may wrap around the fin 104 as shown in FIG. 1, with a channel portion of the fin 104 corresponding to the portion of the fin 104 wrapped by the gate stack 108. In particular, the gate dielectric 110 may wrap around the upper-most portion of the fin 104, and the gate electrode material 112 may wrap around the gate dielectric 110. The interface between the channel portion and the subfin portion of the fin 104 is located proximate to where the gate electrode 112 ends.

The gate electrode material 112 may include at least one P-type work function metal or N-type work function metal, depending on whether the FinFET 100 is a P-type metal oxide semiconductor (PMOS) transistor or an N-type metal oxide semiconductor (NMOS) transistor (P-type work function metal used as the gate electrode 112 when the FinFET 100 is a PMOS transistor and N-type work function metal used as the gate electrode 112 when the FinFET 100 is an NMOS transistor). For a PMOS transistor, metals that may be used for the gate electrode material 112 may include, but are not limited to, ruthenium, palladium, platinum, cobalt, nickel, and conductive metal oxides (e.g., ruthenium oxide). For an NMOS transistor, metals that may be used for the gate electrode material 112 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 112 may include a stack of two or more material, e.g. metal, layers, where one or more material layers are WF material layers as described herein and at least one metal layer is a fill metal layer. Further layers may be included next to the gate electrode material 112 for other purposes, such as to act as a diffusion barrier layer or/and an adhesion layer.

In some embodiments, the gate dielectric 110 may include one or more high-k dielectrics including any of the materials discussed herein with reference to the STI material 106. In some embodiments, an annealing process may be carried out on the gate dielectric 110 during manufacture of the FinFET 100 to improve the quality of the gate dielectric 110. The gate dielectric 110 may have a thickness, a dimension measured in the direction of the y-axis on the sidewalls of the fin 104 and a dimension measured in the direction of the z-axis on top of the fin 104 (the y- and z-axes being different axes of a reference coordinate system x-y-z shown in FIG. 1), that may, in some embodiments, be between 0.5 nanometers and 3 nanometers, including all values and ranges therein (e.g., between 1 and 3 nanometers, or between 1 and 2 nanometers). In some embodiments, the gate stack 108 may be surrounded by a gate spacer, not specifically shown in FIG. 1. The gate spacer is configured to provide separation between the gate stacks 108 of different FinFETs 100 and typically is made of a low-k dielectric material (i.e. a dielectric material that has a lower dielectric constant (k) than silicon dioxide).

In some embodiments, the fin 104 may be composed of semiconductor material systems including, for example, N-type or P-type materials systems. In some embodiments, the fin 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the fin 104 may include a combination of semiconductor materials where one semiconductor material is used for the channel portion and another material, sometimes referred to as a “blocking material,” is used for at least a portion of the subfin portion of the fin 104. In some embodiments, the subfin and the channel portions of the fin 104 are each formed of monocrystalline semiconductors, such as e.g. Si or Ge. In a first embodiment, the subfin and the channel portion of the fin 104 are each formed of compound semiconductors with a first sub-lattice of at least one element from group III of the periodic table (e.g., Al, Ga, In), and a second sub-lattice of at least one element of group V of the periodic table (e.g., P, As, Sb). The subfin may be a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

For exemplary N-type transistor embodiments (i.e. for the embodiments where the FinFET 100 is an N-type transistor), the channel portion of the fin 104 may advantageously include a III-V material having a high electron mobility, such as, but not limited to InGaAs, InP, InSb, and InAs. For some such embodiments, the channel portion of the fin 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portion of the fin 104 may be an intrinsic III-V material, i.e. a III-V semiconductor material not intentionally doped with any electrically active impurity. In alternate embodiments, a nominal impurity dopant level may be present within the channel portion of the fin 104, for example to further fine-tune a threshold voltage Vt, or to provide HALO pocket implants, etc. Even for impurity-doped embodiments however, impurity dopant level within the channel portion of the fin 104 is relatively low, for example below 10¹⁵ dopant atoms per cubic centimeter (cm⁻³), and advantageously below 10¹³ cm⁻³. The subfin portion of the fin 104 may be a III-V material having a band offset (e.g., conduction band offset for N-type devices) from the channel portion. Exemplary materials, include, but are not limited to, GaAs, GaSb, GaAsSb, GaP, InAlAs, GaAsSb, AlAs, AlP, AlSb, and AlGaAs. In some N-type transistor embodiments of the FinFET 100 where the channel portion of the fin 104 is InGaAs, the subfin may be GaAs, and at least a portion of the subfin may also be doped with impurities (e.g., P-type) to a greater impurity level than the channel portion. In an alternate heterojunction embodiment, the subfin and the channel portion of the fin 104 are each group IV semiconductors (e.g., Si, Ge, SiGe). The subfin of the fin 104 may be a first elemental semiconductor (e.g., Si or Ge) or a first SiGe alloy (e.g., having a wide bandgap).

For exemplary P-type transistor embodiments (i.e. for the embodiments where the FinFET 100 is a P-type transistor), the channel portion of the fin 104 may advantageously be a group IV material having a high hole mobility, such as, but not limited to Ge or a Ge-rich SiGe alloy. For some exemplary embodiments, the channel portion of the fin 104 has a Ge content between 0.6 and 0.9, and advantageously is at least 0.7. In some embodiments with highest mobility, the channel portion is intrinsic III-V (or IV for P-type devices) material and not intentionally doped with any electrically active impurity. In alternate embodiments, one or more a nominal impurity dopant level may be present within the channel portion of the fin 104, for example to further set a threshold voltage Vt, or to provide HALO pocket implants, etc. Even for impurity-doped embodiments however, impurity dopant level within the channel portion is relatively low, for example below 10¹⁵ cm⁻³, and advantageously below 10¹³ cm⁻³. The subfin of the fin 104 may be a group IV material having a band offset (e.g., valance band offset for P-type devices) from the channel portion. Exemplary materials, include, but are not limited to, Si or Si-rich SiGe. In some P-type transistor embodiments, the subfin of the fin 104 is Si and at least a portion of the subfin may also be doped with impurities (e.g., N-type) to a higher impurity level than the channel portion.

The fin 104 may include a source region 114 and a drain region 116 (which may be interchanged) on either side of the gate stack 108, as shown in FIG. 1, thus realizing a transistor. As is well known in the art, source and drain regions are formed for the gate stack of each MOS transistor. Although not specifically shown in FIG. 1, the FinFET 100 may further include source and drain electrodes, formed of one or more electrically conductive materials, for providing electrical connectivity to the source and drain regions 114, 116, respectively. S/D regions of the FinFET 100 (also sometimes interchangeably referred to as “diffusion regions”) are regions of doped semiconductors, e.g. regions of doped channel material, so as to supply charge carriers for the transistor channel. Often, the S/D regions are highly doped, e.g. with dopant concentrations of about 1.10²¹ cm⁻³, in order to advantageously form Ohmic contacts with the respective S/D electrodes, although these regions may also have lower dopant concentrations and may form Schottky contacts in some implementations. Irrespective of the exact doping levels, the S/D regions 114, 116 are the regions having dopant concentration higher than in other regions, e.g. higher than a dopant concentration in a region between the source region 114 and the drain region 116, and, therefore, may be referred to as “highly doped” (HD) regions. In some embodiments, the source and drain regions may generally be formed using either an implantation/diffusion process or an etching/deposition process. In the former process, dopants such as boron, aluminum, antimony, phosphorous, or arsenic may be ion-implanted into the fin 104 to form the source and drain regions. An annealing process that activates the dopants and causes them to diffuse further into the fin 104 typically follows the ion implantation process. In the latter process, the fin stack 104 may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. Although not specifically shown in the perspective illustration of FIG. 1, in further embodiments, one or more layers of metal and/or metal alloys are typically used to form the source and drain contacts.

The FinFET 100 may have a gate length (i.e. a distance between the source region 114 and the drain region 116), a dimension measured along the fin 104 in the direction of the x-axis of the exemplary reference coordinate system x-y-z shown in FIG. 1, which may, in some embodiments, be between 5 and 40 nanometers, including all values and ranges therein (e.g. between 22 and 35 nanometers, or between 20 and 30 nanometers). The fin 104 may have a thickness, a dimension measured in the direction of the y-axis of the reference coordinate system x-y-z shown in FIG. 1, that may, in some embodiments, be between 5 and 30 nanometers, including all values and ranges therein (e.g. between 7 and 20 nanometers, or between 10 and 15 nanometers). The fin 104 may have a height, a dimension measured in the direction of the z-axis of the reference coordinate system x-y-z shown in FIG. 1, which may, in some embodiments, be between 30 and 350 nanometers, including all values and ranges therein (e.g. between 30 and 200 nanometers, between 75 and 250 nanometers, or between 150 and 300 nanometers).

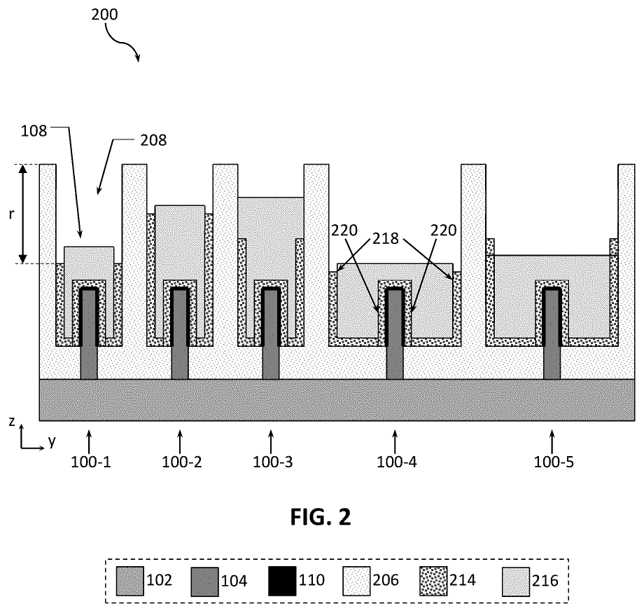

Although the fin 104 illustrated in FIG. 1 is shown as having a rectangular cross section in a z-y plane of the reference coordinate system shown in FIG. 1, the fin 104 may instead have a cross section that is rounded or sloped at the “top” of the fin 104, and the gate stack 108, as well as the WF material layer (not shown in FIG. 1 but shown e.g. in FIG. 2), may conform to this rounded or sloped fin 102. In use, the FinFET 100 may form conducting channels on three “sides” of the channel portion of the fin 104, potentially improving performance relative to single-gate transistors (which may form conducting channels on one “side” of a channel material or substrate) and double-gate transistors (which may form conducting channels on two “sides” of a channel material or substrate).

### Exemplary Transistor Arrangement of One or More FinFETs

While FIG. 1 illustrates a single FinFET 100, in some embodiments, a plurality of FinFETs may be arranged next to one another. FIG. 2 is a cross-sectional side view of one such exemplary transistor arrangement 200, showing multiple FinFETs implementing WF material recess for threshold voltage tuning, according to some embodiments of the disclosure. While the transistor arrangement 200 illustrates 5 exemplary FinETs 100-1 through 100-5 (i.e. each of the FinFETs shown in FIG. 2 may be implemented as the FinFET 100), descriptions provided with respect to the transistor arrangement 200 are applicable to any other number of one or more FinFETs.

The cross-sectional side view of FIG. 2 is the view in the y-z plane of the exemplary coordinate system shown in FIG. 1 with the cross section taken across the fin 104 (e.g. along the plane shown in FIG. 1 as a plane AA), with the same reference numerals used to indicate similar or analogous elements as those shown in FIG. 1 for a single FinFET 100, and different patterns as used in FIG. 2 to illustrate some of the different elements. Thus, the transistor arrangement 200 illustrates the base 102, the fin(s) 104, and the gate dielectric 110, as described with reference to FIG. 1, each of which is shown in FIG. 2 with a different pattern. The transistor arrangement 200 further illustrates the gate stacks 108 (only one of which is labeled in FIG. 2, for the first transistor 100-1, in order to not clutter the drawings). As shown in FIG. 2, in some embodiments, some of the elements of the individual FinFETs of the transistor arrangement 200 may be shared between multiple FinFETs: for example, in FIG. 2, the base 102 is shown to be shared among multiple FinFETs 100-1 through 100-5. In other embodiments when the transistor arrangement 200 includes multiple FinFETs 100, such elements do not have to be shared, or may be shared among lesser, or different, numbers of all of the FinFETs. Other elements are provided individually for each of the multiple FinFETs 100 shown in FIG. 2, e.g. each FinFET of the transistor arrangement 100 includes a respective fin 104, and a respective gate stack 108.

As shown in FIG. 2, the gate stacks 108 of individual FinFETs 100 may be provided in openings 208 (only one of which is illustrated in FIG. 2 in order to not clutter the drawing) in a dielectric material 206 that separates individual FinFETs 100 from one another. In some embodiments, all of the dielectric material 206 may be implemented as the STI 106 described above. In other embodiments, the dielectric material 206 may include the STI 106 enclosing the subfin portions of the fins 104, and a gate spacer material enclosing the upper portions of the fins 104, where the gate spacer may be a different dielectric material from the STI 106. Thus, in such embodiments, the openings 208 may be provided in the gate spacer material above the STI 106. In some embodiments, such a gate spacer may be made of one or more low-k dielectric materials. Examples of low-k materials that may be used to form such a gate spacer may include, but are not limited to, fluorine-doped silicon dioxide, carbon-doped silicon dioxide, spin-on organic polymeric dielectrics such as e.g. polyimide, polynorbornenes, benzocyclobutene, and polytetrafluoroethylene (PTFE), or spin-on silicon-based polymeric dielectric such as e.g. hydrogen silsesquioxane (HSQ) and methylsilsesquioxane (MSQ)). Other examples of low-k materials that may be used in a gate spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1. When such a gate spacer is used, then, similar to the FinFET 100 shown in FIG. 1, the lower portions of the fins 104 of the different FinFETs in the transistor arrangement 200, i.e. the subfin portions of the fins, may be surrounded by the STI 106 which may e.g. include any of the high-k dielectric materials described herein.

As also shown in FIG. 2, the gate stack 108 of a FinFET 100 may include the gate dielectric 110 as described in reference to FIG. 1, a layer of a WF material 214 at least partially surrounding sidewalls of the upper portion of the fin 104 (and, optionally, also the top of the fin 104, as shown in the example of FIG. 2), and a gate fill material 216. When the WF material 214 is used, the WF material 214 and the gate fill material 216 together may be seen as implementing the gate metal 112 of the gate stack 108.

In various embodiments, the gate fill material 216 may include any suitable gate metal material, e.g. as described above with reference to the gate metal 112, while the WF material 214 may include any suitable material other than the gate fill material 216, which, in combination with the gate fill material 216, may control the threshold voltage of each FinFET 100. In various embodiments, the WF material 214 may include any suitable metal, such as e.g. aluminum, titanium, tungsten etc., or any suitable electrically conductive material that is not a metal, such as e.g. a suitable oxide, such as e.g. silicon dioxide, silicon nitride, etc. In one example, the WF material 214 may include titanium nitride, while the gate fill material 216 may include tungsten. In another example, the WF material 214 may include aluminum, while the gate fill material 216 may include tungsten.

The transistor arrangement 200 illustrates an embodiment where the WF material 214 is provided as a liner lining the inner surfaces of the openings 208, recessed within the openings 208 to control the threshold voltage, thus showing an embodiment where the WF material 214 is provided as two sidewalls at least partially enclosing the upper portion of the fin 104. These sidewalls are labeled only for one exemplary FinFET 100 of FIG. 2 (in order to not clutter the drawing), namely for the FinFET 100-4, where the outer sidewall WF layer of the WF material 214 is indicated as a sidewall 218 and the inner sidewall WF layer of the WF material 214 is indicated as a sidewall 220. In such embodiments, the inner sidewall WF layer 220 may at least partially enclose the upper-most portion of the fin 104, e.g. the inner sidewall WF layer 220 may be in contact with and wrap around the upper-most portion of the fin 104. In some embodiments, at least a portion of the gate fill material 216 may be between the outer sidewall WF layer 218 and the fin 104 (thus, the outer sidewall WF layer 218 may be provided at a distance from, i.e. not in contact with, the fin 104), at least a portion of the gate fill material 216 may be between the inner sidewall WF layer 220 and the outer sidewall WF layer 218, and at least a portion of the gate dielectric 110 may be between the inner sidewall WF layer 220 and the fin 104. In some embodiments, the inner sidewall WF layer 220 and the outer sidewall WF layer 218 may be portions of a single continuous WF layer provided as a liner within the respective opening 208, as illustrated in FIG. 2.

In other embodiments, not specifically shown in the FIGS., the inner sidewall WF layer 220 may be absent and only the outer sidewall WF layer 218 present. In such embodiments, the gate dielectric 110 may be in contact with the gate fill material 216.

In various embodiments, the gate dielectric 110 is between the fin 104 and each of the gate fill material 216 and the WF material 214.

Whether the inner sidewall WF layer 220 is present or absent (i.e. for either embodiment), the height of the outer sidewall WF layer 218 may be varied, within each FinFET 100, to control the threshold voltage of each FinFET 100. Thus, in other words, by controlling the height of the WF material that at least partially surrounds the upper portion of a given fin 104 and is provided at a distance to the fin 104 (e.g. by controlling the height of the outer sidewall WF layer 218), the threshold voltage of a FinFET may be controlled.

The height of the WF material 214 on the sidewalls of the openings 208 (e.g. the height of the outer sidewall WF layer 218) may be used to control the height of the gate fill material 216 within the openings, the latter being linked to affecting the threshold voltage of a FinFET. Thus, according to various embodiments of the disclosure, the height of the WF material 214, and, therefore, the height of the fill of the opening 208 with the gate fill material 216, may be varied to control the threshold voltage of each FinFET 100, which is illustrated in FIG. 2 with different FinFETs 100 having different heights for the outer sidewall WF layer 218 and for the gate fill material 216. Thus, different FinFETs 100 shown in FIG. 2 may be designed to have different threshold voltages by having different heights of their outer sidewall WF layers 218, which height may be controlled, in some embodiments, by appropriately recessing the outer sidewall WF layer 218 in each opening 208. For example, in some embodiments, for the FinFET 100-1, the recess (labeled in FIG. 2 as a distance “r” for this particular FinFET; recesses for other FinFETs not specifically labeled in FIG. 2 in order to not clutter the drawing) may be about 70 nanometers; for the FinFET 100-2, the recess of the outer sidewall WF layer 218 may be about 20 nanometers; for the FinFET 100-3, the recess of the outer sidewall WF layer 218 may be about 50 nanometers; for the FinFET 100-4, the recess of the outer sidewall WF layer 218 may be about 80 nanometers; and, for the FinFET 100-5, the recess of the outer sidewall WF layer 218 may be about 50 nanometers. In some embodiments, the height of the outer sidewall WF layer 218 may vary, from one FinFET 100 to another, by anywhere between zero (i.e. no recess of the outer sidewall WF layer 218 in the opening 208) and about 200 nanometers, including all values and ranges therein, for example anywhere between about 5 and 100 nanometers, or anywhere between about 10 and 80 nanometers.

In various embodiments, for each FinFET 100, at least a portion of the gate fill material 216 may be between the WF material 214 and the fin 104.

In some embodiments, irrespective of the absolute value of the height of the outer sidewall WF layer 218, the gate fill material 216 of some of the FinFETs 100 of the transistor arrangement 200 may extend farther away from the base 102 than the sidewall WF layer of the WF material 214 of those transistors. Such examples are illustrated in FIG. 2 with the FinFETs 100-1 through 100-4.

In other embodiments, irrespective of the absolute value of the height of the outer sidewall WF layer 218, the sidewall WF layer of the WF material 214 of some of the FinFETs 100 of the transistor arrangement 200 may extend farther away from the base 102 than the gate fill material 216. Such an example is illustrated in FIG. 2 with the FinFET 100-5.

In some embodiments, the gate fill material 216 may be provided above the top of the fin 104, as illustrated for all of the FinFETs 100 shown in FIG. 2.

In some embodiments, the gate fill material 216 may be in contact with the sidewalls of the openings 208 in the dielectric material 206, i.e. in contact with the dielectric material 206, as illustrated in FIG. 2 for the FinFET 100-3.

The transistor arrangements such as the transistor arrangement 200 illustrated in FIG. 2 and different variations of such an arrangement, as described above, do not represent an exhaustive set of transistor arrangements in which WF material recess may be used to control a threshold voltage of one of more FinFETs but merely provide examples of such arrangements. Although particular arrangements of materials are discussed with reference to FIGS. 1-2, intermediate materials may be included in the transistor devices of these FIGS. Note that FIGS. 1-2 are intended to show relative arrangements of the components therein, and that transistor arrangements of these FIGS may include other components that are not illustrated (e.g., S/D electrodes or various interfacial layers). Additionally, although various components of the transistor arrangements are illustrated in FIGS. 1-2 as being planar rectangles or formed of rectangular solids, this is simply for ease of illustration, and embodiments of these transistors may be curved, rounded, or otherwise irregularly shaped as dictated by, and sometimes inevitable due to, the manufacturing processes used to fabricate various components.

### Exemplary Method of Manufacturing

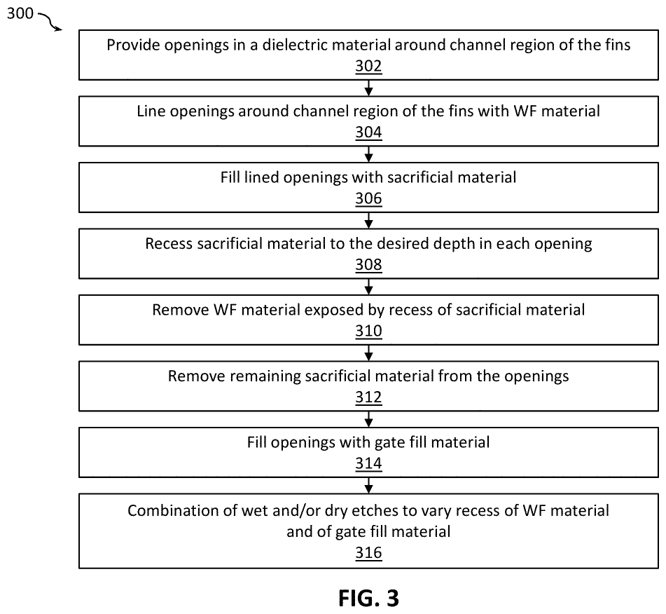

Transistor arrangements with one or more FinFETs implementing WF material recess to control threshold voltage as disclosed herein may be manufactured using any suitable techniques. FIG. 3 is a flow diagram summarizing one example method 300 of manufacturing a transistor arrangement with one or more FinFETs using WF material recess for threshold voltage tuning, e.g. the transistor arrangement 200, in accordance with various embodiments.

Although the operations of the method 300 are illustrated once each and in a particular order, the operations may be performed in any suitable order and repeated as desired. For example, one or more operations may be performed in parallel to manufacture multiple transistor arrangements substantially simultaneously. In another example, the operations may be performed in a different order to reflect the structure of a particular device in which a transistor arrangement implementing WF material recess to control threshold voltage of one or more FinFETs may be included. Furthermore, the method 300 may further include other manufacturing operations related to fabrication of other components of the transistor arrangements described herein, or any devices that include such arrangements. For example, the method 300 may various cleaning operations, surface planarization operations (e.g. using chemical mechanical polishing), operations to include barrier and/or adhesion layers as needed, and/or operations for incorporating the transistor arrangements as described herein in, or with, an IC component.

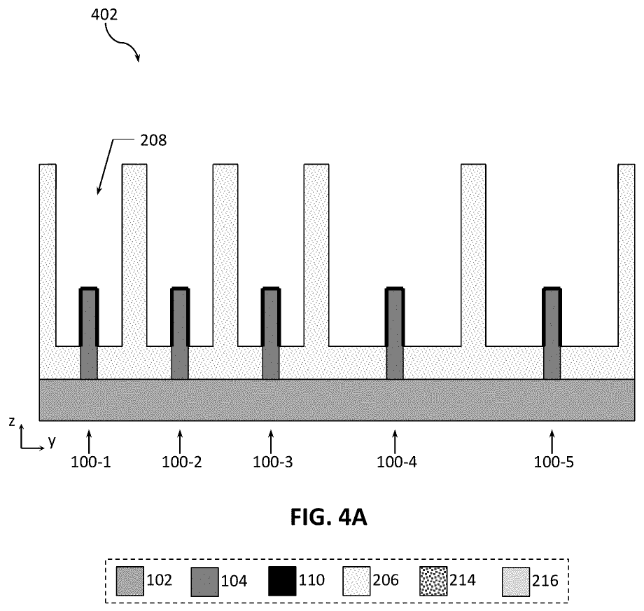

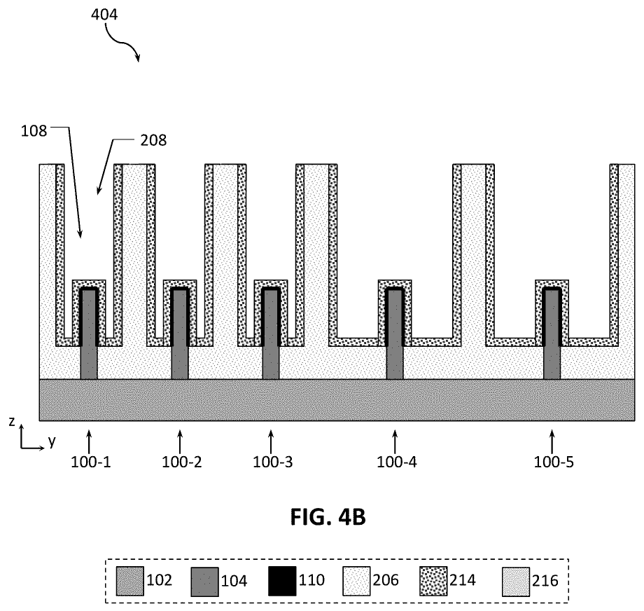

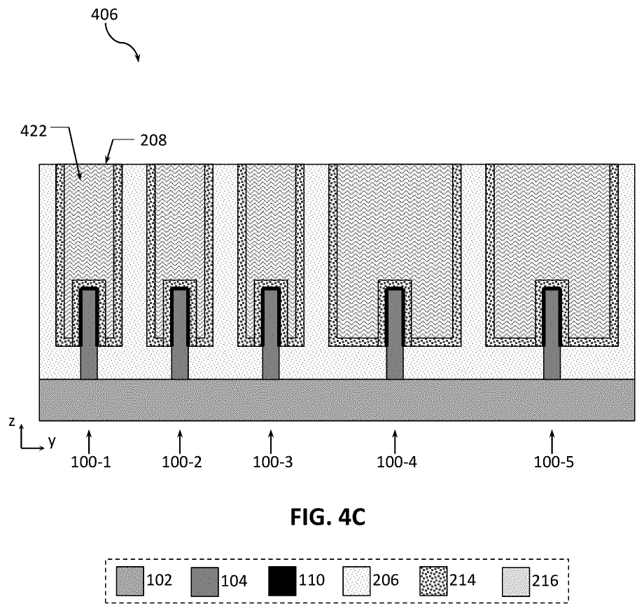

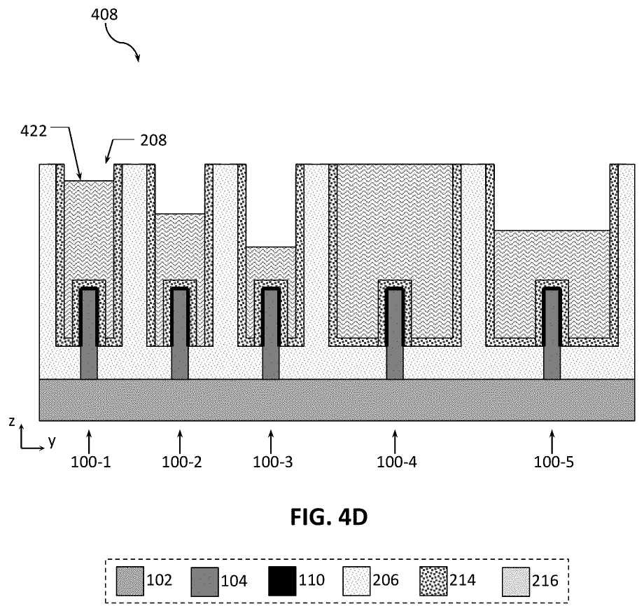

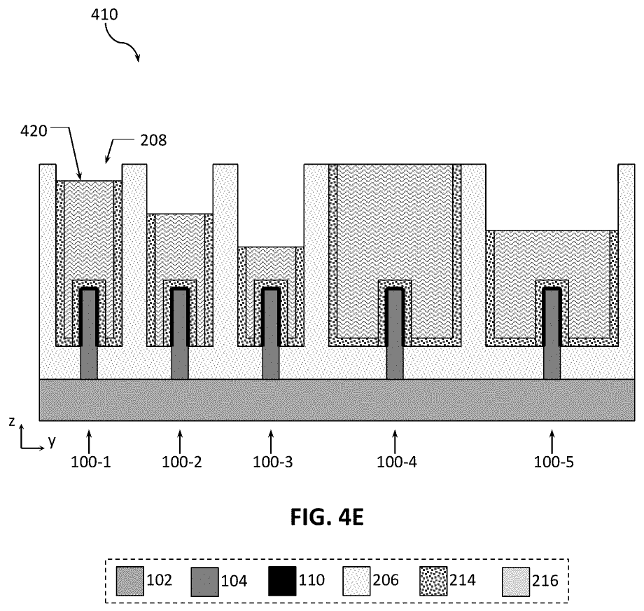

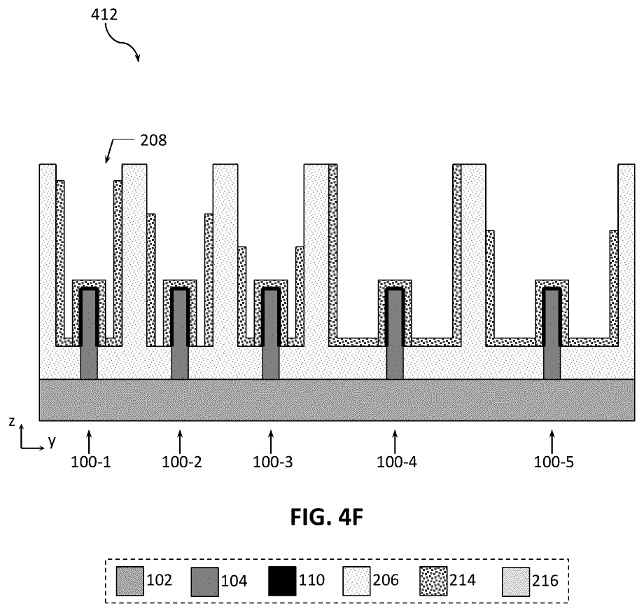

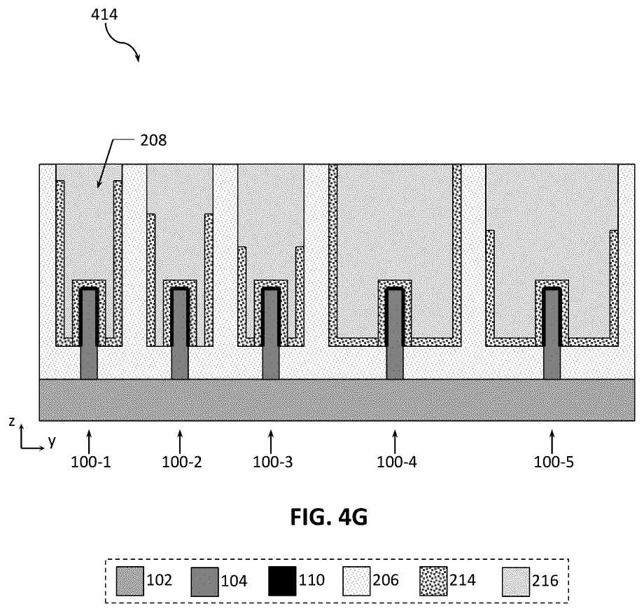

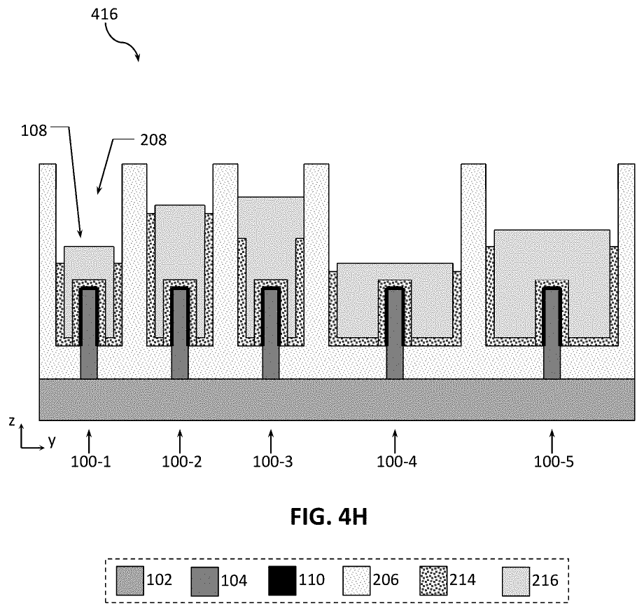

FIGS. 4A-4H illustrate various example stages in the manufacturing process outlined in FIG. 3, in accordance with some embodiments of the disclosure. While FIGS. 4A-4H are illustrated for the example of manufacturing the transistor arrangement 200 as depicted in FIG. 2 (i.e. an example of a transistor arrangement having multiple FinFETs with different heights of a common WF material), discussions provided herein with respect to manufacturing the transistor arrangement 200 may be easily extended/modified to be applicable to all other transistor arrangement embodiments discussed herein. For the sake of consistency, the legend and patterns used in FIGS. 4A-4H are the same as the legend and patterns used in FIGS. 1 and 2.

Since FIGS. 4A-4H are intended to provide an illustration of an example of manufacturing of the transistor arrangement 200, in particular the arrangement as shown in FIG. 2, all of the descriptions provided above with respect to reference numerals indicated in FIG. 2 are applicable to 4A-4H and are not repeated. On the other hand, although the particular manufacturing operations discussed below with reference to FIG. 3 are illustrated in 4A-4H as manufacturing particular embodiments of the arrangement as shown in FIG. 2, these operations may be applied to manufacture many different embodiments of various transistor arrangements as discussed herein. Any of the elements discussed below with reference to 4A-4H may take the form of any of the embodiments of those elements discussed above (or otherwise disclosed herein).

The method 300 shown in FIG. 3 may begin with forming a plurality of fins, each fin extending away from a base and enclosed by one or more insulating materials, e.g. the fins 104 extending away from the base 102, and enclosed by the dielectric material 206, as described herein. Next, the method 300 may include a process 302, in which one or more openings are provided in a dielectric material around channel regions of the one or more fins of different FinFETs provided on a substrate. A result of the process 302 is illustrated in FIG. 4A showing a transistor assembly 402 where 5 openings 208 (only one of which is labeled) are provided in the dielectric material 206 around 5 fins 104, respectively. Each of the fins 104 belong to a different one of 5 FinFETs 100, also labeled in FIG. 4A. The transistor assembly 402 further indicates the gate dielectric 110 lining the portions of the fins 104 exposed by the openings 208. Any suitable known techniques for forming openings 208 in the dielectric material 206 may be used to form the openings in the process 302, such as e.g. any suitable etching techniques, possibly in combination with using masks or any suitable patterning techniques, such as e.g. photolithographic or electron-beam patterning. Similarly, any suitable known techniques may be used for providing the gate dielectric 110 around the channel portions of the fins 104, where the gate dielectric 110 may be provided either after the openings 208 are formed, or before the fins 104 are enclosed with the dielectric material 206.

The method 300 may then continue with a process 304, where at least some of the openings provided in the process 302 may be lined with the WF material. A result of the process 304 is illustrated in FIG. 4B showing a transistor assembly 404, illustrating that the inner surfaces of all 5 openings 208 of the transistor assembly 402 are now lined with the WF material 214. Any suitable known techniques for conformally lining exposed surfaces with materials which may be used for the WF material 214 may be used to line the inner surfaces of the openings 208 in the process 304, such as e.g. any suitable conformal deposition techniques, such as e.g. atomic layer deposition (ALD). In various embodiments, a thickness of the layer of the WF material 214 deposited in the process 304 may be between about 2 and 10 nanometers, including all values and ranges therein, e.g. between about 2 and 7 nanometers or between about 4 and 7 nanometers.

Next, in a process 306, the openings 208 lined with the WF material 214 may be filled with a sacrificial material. A result of the process 306 is illustrated in FIG. 4C showing a transistor assembly 406, illustrating that the lined openings 208 of the transistor assembly 404 are now filled with the sacrificial material 422. The sacrificial material 422 may be any suitable material that is sufficiently etch selective with respect to the WF material 214 so that, in a subsequent process, the sacrificial material 422 may be etched to the desired depth which will control the later formed recess of the WF material 214. As known in the art, two materials are said to have “sufficient etch selectivity” when etchants used to etch one material do not substantially etch the other, enabling selective etching of one material without substantially etching the other. The material 422 deposited in the lined openings in the process 306 is referred to as “sacrificial” because most, preferably all, of this material will be removed in the final transistor arrangement.

In some embodiments, the sacrificial material 422 may be a sacrificial dielectric material, such as e.g. any of the low-k or high-k dielectric materials as commonly used in semiconductor processing, including but not limited to elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used as the sacrificial material 422 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. Examples of low-k materials that may be used as the sacrificial material 422 may include, but are not limited to, fluorine-doped silicon dioxide, carbon-doped silicon dioxide, spin-on organic polymeric dielectrics such as e.g. polyimide, polynorbornenes, benzocyclobutene, and polytetrafluoroethylene (PTFE), or spin-on silicon-based polymeric dielectric such as e.g. hydrogen silsesquioxane (HSQ) and methylsilsesquioxane (MSQ)). Any suitable deposition techniques may be used to provide the sacrificial material 422 within the lined openings 208. Some examples of such techniques include spin-coating, dip-coating, chemical vapor deposition (CVD), plasma enhanced CVD (PECVD), ALD, or thermal oxidation.

The method 300 may then continue with a process 308, where the sacrificial material 422 is recessed in at least some of the openings filled in the process 306. A result of the process 308 is illustrated in FIG. 4D showing a transistor assembly 408, illustrating that the sacrificial material 422 may be recessed to different degrees within different openings 208 (in some openings 208 the sacrificial material 422 may not be recessed, as also illustrated in FIG. 4D). In other embodiments, recess of the sacrificial material 422 may be the same for at least some, possibly all, of the openings 208. Any suitable known techniques for removing the sacrificial material 422 may be used to recess the sacrificial material 422 in different openings 208 in the process 308, such as e.g. any suitable patterning and etching techniques.

As a result of recessing the sacrificial material 422 within at least some of the openings 208, some of the WF material 214 may become exposed (the WF material 214 was previously substantially covered with the sacrificial material 422 when the sacrificial material 422 was deposited in the process 306). The method 300 may then include a process 310, in which the WF material 214 exposed by the recess of the sacrificial material 422 may be removed. A result of the process 310 is illustrated in FIG. 4E showing a transistor assembly 410, illustrating that portions of the WF material 214 are removed so that the WF material 214 is substantially aligned with the sacrificial material 422 in each of the openings 208, thus providing a recess in the WF material 214. Any suitable known techniques for removing the exposed WF material 214 may be used to create the recesses in the WF material 214 in each of the openings 208, as needed, in the process 310, such as e.g. any suitable wet etching techniques.

Once the desired recesses are created in the WF material 214, the remaining portions of the sacrificial material 422 may be removed, in a process 312 shown in FIG. 3. A result of the process 312 is illustrated in FIG. 4F showing a transistor assembly 412, illustrating that substantially all of the sacrificial material 422 is removed from each of the openings 208, leaving recessed WF material 214. Any suitable known techniques for removing the sacrificial material 422 may be used to remove the sacrificial material 422 in the process 312, such as e.g. any of the techniques used in the process 308, or any other techniques, e.g. any suitable dry etch techniques.

The method 300 may then proceed with a process 314 that includes filling the openings 208 of the transistor arrangement 412 with a gate fill material. A result of the process 314 is illustrated in FIG. 4G showing a transistor assembly 414, illustrating that the lined openings 208 of the transistor assembly 412 are now filled with the gate fill material 216. Any suitable known techniques for depositing gate electrode materials may be used to deposit the gate fill material 216 in the openings 208 in the process 314, such as e.g. ALD, CVD, PECVD, sputtering, electroplating, or any other suitable metal deposition techniques.

The method 300 may further include a process 316, in which any suitable combination of wet and/or dry etch techniques may be implemented to further vary the recess of the WF material 214 as well as, optionally, also vary the recess of the gate fill material 216 in each of the openings 208 until the geometry of the WF material 214 and the gate fill material 216 within each opening is such as to lead to the desired threshold voltage for the FinFET associated with the opening. A result of the process 316 is illustrated in FIG. 4H showing a transistor assembly 416, illustrating exemplary variations in the recess of the WF material 214 and in the recess of the gate fill material 216 in different openings 208. Any suitable known etching techniques may be used in the process 316, such as e.g. ALD, CVD, PECVD, sputtering, electroplating, or any other suitable metal deposition techniques.

Many variations are possible to the method 300 shown in FIG. 3 and further illustrated in FIGS. 4A-4H, all of which being within the scope of the present disclosure. For example, in some embodiments, two different WF metals could be deposited inside the gates at the process 304 of the method 300. In such embodiments, instead of one WF material being deposited, the process 304 may include depositing a first WF material (WF1) deposited, e.g. using an ALD process, inside the gate, and then depositing a second WF material (WF2) on top of the WF1. In such embodiments, the wet etch could have a different etch rate for each of the multiple WF materials and, hence, the overall recess of the gate metal and WF material may vary, resulting in differing threshold voltages.

### Exemplary Devices

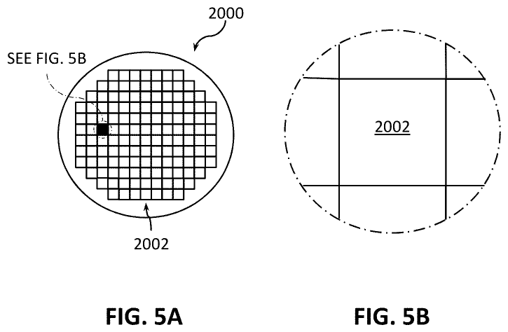

Transistor arrangements with one or more FinFETs implementing WF material recess to control threshold voltage as disclosed herein may be included in any suitable electronic device. FIGS. 5A-5B and 6-8 illustrate various examples of structures and apparatuses that may include one or more of such transistor arrangements.

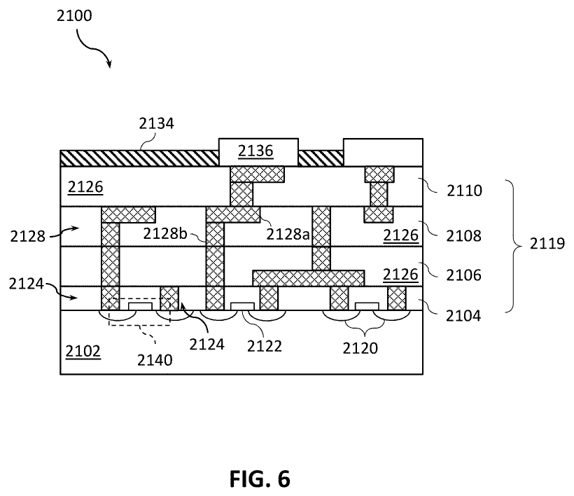

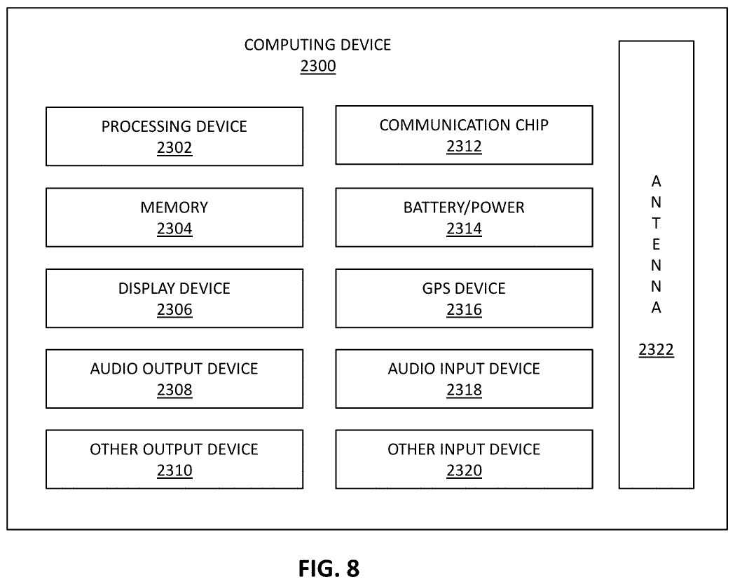

FIGS. 5A-B are top views of a wafer 2000 and dies 2002 that may include one or more transistor arrangements implementing WF material recess to control threshold voltage of one or more FinFETs in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more transistor arrangements 200, or any other transistor arrangements implementing WF material recess to control threshold voltage of one or more FinFETs as described herein). After the fabrication of the semiconductor product is complete (e.g., after manufacture of one or more transistor arrangements 200, or any other transistor arrangements implementing WF material recess to control threshold voltage of one or more FinFETs as described herein), the wafer 2000 may undergo a singulation process in which each of the dies 2002 is separated from one another to provide discrete “chips” of the semiconductor product. In particular, devices that include one or more transistor arrangements as disclosed herein may take the form of the wafer 2000 (e.g., not singulated) or the form of the die 2002 (e.g., singulated). The die 2002 may include one or more transistors (e.g., one or more of the transistors 2140 of FIG. 6, discussed below, at least some of which may take the form of any of the FinFETs implementing WF material recess to control threshold voltage as described herein) and/or supporting circuitry to route electrical signals to the transistors, as well as any other IC components. In some embodiments, the wafer 2000 or the die 2002 may include a memory device (e.g., a static random access memory (SRAM) device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2302 of FIG. 8) or other logic that is configured to store information in the memory devices or execute instructions stored in the memory array.

FIG. 6 is a cross-sectional side view of an IC device 2100 that may include one or more transistor arrangements implementing WF material recess to control threshold voltage of one or more FinFETs in accordance with any of the embodiments disclosed herein. The IC device 2100 may be formed on a substrate 2102 (e.g., the wafer 2000 of FIG. 5A) and may be included in a die (e.g., the die 2002 of FIG. 5B). The substrate 2102 may be a semiconductor substrate composed of semiconductor material systems including, for example, N-type or P-type materials systems. The substrate 2102 may include, for example, a crystalline substrate formed using a bulk silicon or a silicon-on-insulator substructure. In some embodiments, the semiconductor substrate 2102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the substrate 2102. Although a few examples of materials from which the substrate 2102 may be formed are described here, any material that may serve as a foundation for an IC device 2100 may be used. The substrate 2102 may be part of a singulated die (e.g., the die 2002 of FIG. 5B) or a wafer (e.g., the wafer 2000 of FIG. 5A).

The IC device 2100 may include one or more device layers 2104 disposed on the substrate 2102. The device layer 2104 may include features of one or more transistors 2140 (e.g., metal oxide semiconductor FETs (MOSFETs)) formed on the substrate 2102. The device layer 2104 may include, for example, one or more source and/or drain (S/D) regions 2120, a gate 2122 to control current flow in the transistors 2140 between the S/D regions 2120, and one or more S/D contacts 2124 to route electrical signals to/from the S/D regions 2120. Even though not specifically illustrated in FIG. 6, at least some of the one or more transistors 2140 may include any of the FinFETs implementing WF material recess to control their threshold voltage as described herein. Thus, the gates 2122 of at least some of the transistors of any of the device layers 2104 may include the WF material 214 and the gate fill material 216 as described above. Various transistors 2140 are not limited to the type and configuration depicted in FIG. 6 and may include a wide variety of other types and configurations such as, for example, planar transistors, non-planar transistors, or a combination of both, at least some of which could be used to one or more transistor arrangements 200, or any other transistor arrangements implementing WF material recess to control threshold voltage of one or more FinFETs as described herein. Besides FinFETs, other non-planar transistors 2140 may include wrap around or all-around gate transistors, such as nanoribbon and nanowire transistors. The transistors 2140 may include additional features not depicted for the sake of clarity, such as device isolation regions, gate contacts, and the like.

Each transistor 2140 may include a gate 2122 formed of at least two layers, a gate dielectric layer and a gate electrode layer. Generally, the gate dielectric layer of a transistor 2140 may include one layer or a stack of layers, and the one or more layers may include silicon oxide, silicon dioxide, and/or a high-k dielectric material. The high-k dielectric material included in the gate dielectric layer of the transistor 2140 may take the form of any of the embodiments of the high-k dielectric 110 disclosed herein, for example.

In some embodiments, when viewed as a cross section of the transistor 2140 along the source-channel-drain direction, the gate electrode may include a U-shaped structure that includes a bottom portion substantially parallel to the surface of the substrate and two sidewall portions that are substantially perpendicular to the top surface of the substrate (e.g., as illustrated for the FinFETs of FIGS. 1 and 2). In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may include a combination of U-shaped structures and planar, non-U-shaped structures. For example, the gate electrode may include one or more U-shaped metal layers formed atop one or more planar, non-U-shaped layers. In some embodiments, the gate electrode may include a V-shaped structure (e.g., when the fin of a FinFET does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2120 may be formed within the substrate 2102, as described herein. For example, at least some of the S/D regions 2120 formed within the substrate 2102 may include the S/D regions 114, 116 described above. The S/D regions 2120 may be formed within the substrate 2102 using any suitable processes known in the art, some of which are described above.

Electrical signals, such as power and/or input/output (I/O) signals, may be routed to and/or from the transistors 2140 of the device layer 2104 through one or more interconnect layers disposed on the device layer 2104 (illustrated in FIG. 6 as interconnect layers 2106-2110). For example, electrically conductive features of the device layer 2104 (e.g., the gate 2122 and the S/D contacts 2124) may be electrically coupled with the interconnect structures 2128 of the interconnect layers 2106-2110. The one or more interconnect layers 2106-2110 may form an interlayer dielectric (ILD) stack 2119 of the IC device 2100.

The interconnect structures 2128 may be arranged within the interconnect layers 2106-1210 to route electrical signals according to a wide variety of designs (in particular, the arrangement is not limited to the particular configuration of interconnect structures 2128 depicted in FIG. 6). Although a particular number of interconnect layers 2106-1210 is depicted in FIG. 6, embodiments of the present disclosure include IC devices having more or fewer interconnect layers than depicted.

In some embodiments, the interconnect structures 2128 may include trench structures 2128a (sometimes referred to as “lines”) and/or via structures 2128b (sometimes referred to as “holes”) filled with an electrically conductive material such as a metal. The trench structures 2128a may be arranged to route electrical signals in a direction of a plane that is substantially parallel with a surface of the substrate 2102 upon which the device layer 2104 is formed. For example, the trench structures 2128a may route electrical signals in a direction in and out of the page from the perspective of FIG. 6. The via structures 2128b may be arranged to route electrical signals in a direction of a plane that is substantially perpendicular to the surface of the substrate 2102 upon which the device layer 2104 is formed. In some embodiments, the via structures 2128b may electrically couple trench structures 2128a of different interconnect layers 2106-2110 together.

The interconnect layers 2106-2110 may include a dielectric material 2126 disposed between the interconnect structures 2128, as shown in FIG. 6. In some embodiments, the dielectric material 2126 disposed between the interconnect structures 2128 in different ones of the interconnect layers 2106-2110 may have different compositions; in other embodiments, the composition of the dielectric material 2126 between different interconnect layers 2106-2110 may be the same.

A first interconnect layer 2106 (referred to as Metal 1 or “M1”) may be formed directly on the device layer 2104. In some embodiments, the first interconnect layer 2106 may include trench structures 2128a and/or via structures 2128b, as shown. The trench structures 2128a of the first interconnect layer 2106 may be coupled with contacts (e.g., the S/D contacts 2124) of the device layer 2104.

A second interconnect layer 2108 (referred to as Metal 2 or “M2”) may be formed directly on the first interconnect layer 2106. In some embodiments, the second interconnect layer 2108 may include via structures 2128b to couple the trench structures 2128a of the second interconnect layer 2108 with the trench structures 2128a of the first interconnect layer 2106. Although the trench structures 2128a and the via structures 2128b are structurally delineated with a line within each interconnect layer (e.g., within the second interconnect layer 2108) for the sake of clarity, the trench structures 2128a and the via structures 2128b may be structurally and/or materially contiguous (e.g., simultaneously filled during a dual-damascene process) in some embodiments.

A third interconnect layer 2110 (referred to as Metal 3 or “M3”) (and additional interconnect layers, as desired) may be formed in succession on the second interconnect layer 2108 according to similar techniques and configurations described in connection with the second interconnect layer 2108 or the first interconnect layer 2106.

The IC device 2100 may include a solder resist material 2134 (e.g., polyimide or similar material) and one or more bond pads 2136 formed on the interconnect layers 2106-2110. The bond pads 2136 may be electrically coupled with the interconnect structures 2128 and configured to route the electrical signals of the transistor(s) 2140 to other external devices. For example, solder bonds may be formed on the one or more bond pads 2136 to mechanically and/or electrically couple a chip including the IC device 2100 with another component (e.g., a circuit board). The IC device 2100 may have other alternative configurations to route the electrical signals from the interconnect layers 2106-2110 than depicted in other embodiments. For example, the bond pads 2136 may be replaced by or may further include other analogous features (e.g., posts) that route the electrical signals to external components.

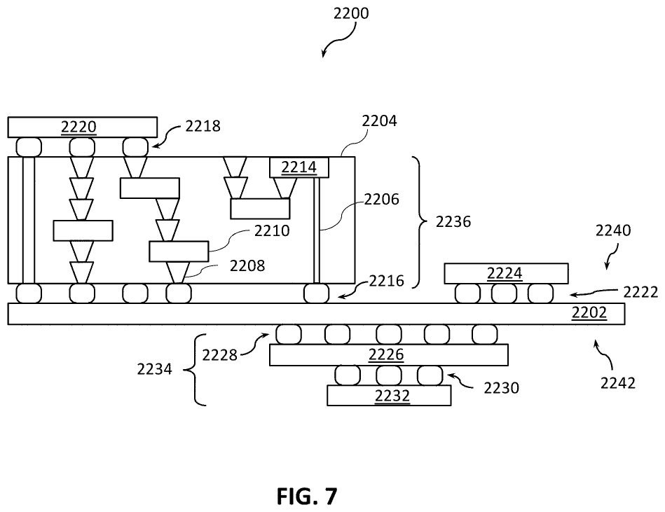

FIG. 7 is a cross-sectional side view of an IC device assembly 2200 that may include components having one or more transistor arrangements implementing WF material recess to control threshold voltage of one or more FinFETs in accordance with any of the embodiments disclosed herein. The IC device assembly 2200 includes a number of components disposed on a circuit board 2202 (which may be, e.g., a motherboard). The IC device assembly 2200 includes components disposed on a first face 2240 of the circuit board 2202 and an opposing second face 2242 of the circuit board 2202; generally, components may be disposed on one or both faces 2240 and 2242. In particular, any suitable ones of the components of the IC device assembly 2200 may include any of the transistor arrangements implementing WF material recess to control threshold voltage of one or more FinFETs in accordance with any of the embodiments disclosed herein.

In some embodiments, the circuit board 2202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2202. In other embodiments, the circuit board 2202 may be a non-PCB substrate.

The IC device assembly 2200 illustrated in FIG. 7 includes a package-on-interposer structure 2236 coupled to the first face 2240 of the circuit board 2202 by coupling components 2216. The coupling components 2216 may electrically and mechanically couple the package-on-interposer structure 2236 to the circuit board 2202, and may include solder balls (as shown in FIG. 7), male and female portions of a socket, an adhesive, an underfill material, and/or any other suitable electrical and/or mechanical coupling structure.

The package-on-interposer structure 2236 may include an IC package 2220 coupled to an interposer 2204 by coupling components 2218. The coupling components 2218 may take any suitable form for the application, such as the forms discussed above with reference to the coupling components 2216. The IC package 2220 may be or include, for example, a die (the die 2002 of FIG. 5B), an IC device (e.g., the IC device 2100 of FIG. 6), or any other suitable component. In particular, the IC package 2220 may include one or more transistor arrangements 200, or any other transistor arrangements implementing WF material recess to control threshold voltage of one or more FinFETs as described herein. Although a single IC package 2220 is shown in FIG. 7, multiple IC packages may be coupled to the interposer 2204; indeed, additional interposers may be coupled to the interposer 2204. The interposer 2204 may provide an intervening substrate used to bridge the circuit board 2202 and the IC package 2220. Generally, the interposer 2204 may spread a connection to a wider pitch or reroute a connection to a different connection. For example, the interposer 2204 may couple the IC package 2220 (e.g., a die) to a ball grid array (BGA) of the coupling components 2216 for coupling to the circuit board 2202. In the embodiment illustrated in FIG. 7, the IC package 2220 and the circuit board 2202 are attached to opposing sides of the interposer 2204; in other embodiments, the IC package 2220 and the circuit board 2202 may be attached to a same side of the interposer 2204. In some embodiments, three or more components may be interconnected by way of the interposer 2204.

The interposer 2204 may be formed of an epoxy resin, a fiberglass-reinforced epoxy resin, a ceramic material, or a polymer material such as polyimide. In some implementations, the interposer 2204 may be formed of alternate rigid or flexible materials that may include the same materials described above for use in a semiconductor substrate, such as silicon, germanium, and other group III-V and group IV materials. The interposer 2204 may include metal interconnects 2208 and vias 2210, including but not limited to through-silicon vias (TSVs) 2206. The interposer 2204 may further include embedded devices 2214, including both passive and active devices. Such devices may include, but are not limited to, capacitors, decoupling capacitors, resistors, inductors, fuses, diodes, transformers, sensors, ESD devices, and memory devices. In particular, one or more transistor arrangements implementing WF material recess to control threshold voltage of one or more FinFETs may be included within at least some of the embedded devices 2214. More complex devices such as radio frequency (RF) devices, power amplifiers, power management devices, antennas, arrays, sensors, and microelectromechanical systems (MEMS) devices may also be formed on the interposer 2204. The package-on-interposer structure 2236 may take the form of any of the package-on-interposer structures known in the art.

The IC device assembly 2200 may include an IC package 2224 coupled to the first face 2240 of the circuit board 2202 by coupling components 2222. The coupling components 2222 may take the form of any of the embodiments discussed above with reference to the coupling components 2216, and the IC package 2224 may take the form of any of the embodiments discussed above with reference to the IC package 2220.

The IC device assembly 2200 illustrated in FIG. 7 includes a package-on-package structure 2234 coupled to the second face 2242 of the circuit board 2202 by coupling components 2228. The package-on-package structure 2234 may include an IC package 2226 and an IC package 2232 coupled together by coupling components 2230 such that the IC package 2226 is disposed between the circuit board 2202 and the IC package 2232. The coupling components 2228 and 2230 may take the form of any of the embodiments of the coupling components 2216 discussed above, and the IC packages 2226 and 2232 may take the form of any of the embodiments of the IC package 2220 discussed above. The package-on-package structure 2234 may be configured in accordance with any of the package-on-package structures known in the art.

FIG. 8 is a block diagram of an example computing device 2300 that may include one or more components with one or more transistor arrangements implementing WF material recess to control threshold voltage of one or more FinFETs in accordance with any of the embodiments disclosed herein. For example, any suitable ones of the components of the computing device 2300 may include a die (e.g., the die 2002 (FIG. 5B)) having one or more transistor arrangements in accordance with any of the embodiments disclosed herein. Any one or more of the components of the computing device 2300 may include, or be included in, an IC device 2100 (FIG. 6). Any one or more of the components of the computing device 2300 may include, or be included in, an IC device assembly 2200 (FIG. 7).

A number of components are illustrated in FIG. 8 as included in the computing device 2300, but any one or more of these components may be omitted or duplicated, as suitable for the application. In some embodiments, some or all of the components included in the computing device 2300 may be attached to one or more motherboards. In some embodiments, some or all of these components are fabricated onto a single system-on-a-chip (SoC) die.

Additionally, in various embodiments, the computing device 2300 may not include one or more of the components illustrated in FIG. 8, but the computing device 2300 may include interface circuitry for coupling to the one or more components. For example, the computing device 2300 may not include a display device 2306, but may include display device interface circuitry (e.g., a connector and driver circuitry) to which a display device 2306 may be coupled. In another set of examples, the computing device 2300 may not include an audio input device 2324 or an audio output device 2308, but may include audio input or output device interface circuitry (e.g., connectors and supporting circuitry) to which an audio input device 2324 or audio output device 2308 may be coupled.

The computing device 2300 may include a processing device 2302 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2300 may include a memory 2304, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 2304 may include memory that shares a die with the processing device 2302. This memory may be used as cache memory and may include embedded dynamic random access memory (eDRAM) or spin transfer torque magnetic random access memory (STT-MRAM).

In some embodiments, the computing device 2300 may include a communication chip 2312 (e.g., one or more communication chips). For example, the communication chip 2312 may be configured for managing wireless communications for the transfer of data to and from the computing device 2300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2312 may operate in accordance with other wireless protocols in other embodiments. The computing device 2300 may include an antenna 2322 to facilitate wireless communications and/or to receive other wireless communications (such as AM or FM radio transmissions).

In some embodiments, the communication chip 2312 may manage wired communications, such as electrical, optical, or any other suitable communication protocols (e.g., the Ethernet). As noted above, the communication chip 2312 may include multiple communication chips. For instance, a first communication chip 2312 may be dedicated to shorter-range wireless communications such as Wi-Fi or Bluetooth, and a second communication chip 2312 may be dedicated to longer-range wireless communications such as global positioning system (GPS), EDGE, GPRS, CDMA, WiMAX, LTE, EV-DO, or others. In some embodiments, a first communication chip 2312 may be dedicated to wireless communications, and a second communication chip 2312 may be dedicated to wired communications.

The computing device 2300 may include battery/power circuitry 2314. The battery/power circuitry 2314 may include one or more energy storage devices (e.g., batteries or capacitors) and/or circuitry for coupling components of the computing device 2300 to an energy source separate from the computing device 2300 (e.g., AC line power).

The computing device 2300 may include a display device 2306 (or corresponding interface circuitry, as discussed above). The display device 2306 may include any visual indicators, such as a heads-up display, a computer monitor, a projector, a touchscreen display, a liquid crystal display (LCD), a light-emitting diode display, or a flat panel display, for example.

The computing device 2300 may include an audio output device 2308 (or corresponding interface circuitry, as discussed above). The audio output device 2308 may include any device that generates an audible indicator, such as speakers, headsets, or earbuds, for example.

The computing device 2300 may include an audio input device 2318 (or corresponding interface circuitry, as discussed above). The audio input device 2318 may include any device that generates a signal representative of a sound, such as microphones, microphone arrays, or digital instruments (e.g., instruments having a musical instrument digital interface (MIDI) output).

The computing device 2300 may include a GPS device 2316 (or corresponding interface circuitry, as discussed above). The GPS device 2316 may be in communication with a satellite-based system and may receive a location of the computing device 2300, as known in the art.

The computing device 2300 may include an other output device 2310 (or corresponding interface circuitry, as discussed above). Examples of the other output device 2310 may include an audio codec, a video codec, a printer, a wired or wireless transmitter for providing information to other devices, or an additional storage device.

The computing device 2300 may include an other input device 2320 (or corresponding interface circuitry, as discussed above). Examples of the other input device 2320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2300 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2300 may be any other electronic device that processes data.

### Select Examples

The following paragraphs provide various examples of the embodiments disclosed herein.

Example 1 provides a transistor arrangement that includes a first and a second transistors. The first transistor includes a fin extending away from a base, and a sidewall WF layer of a first WF material at least partially surrounding sidewalls of an upper portion (the upper-most portion) of the fin of the first transistor. The second transistor includes a fin extending away from the base, and a sidewall WF layer of a second WF material (which could be the same or different from the first WF material) at least partially surrounding sidewalls of an upper portion (the upper-most portion) of the fin of the second transistor, where, in a direction substantially parallel to a height of the fin of the first or the second transistor (e.g. in a direction substantially perpendicular to the base), a height of the first WF material (i.e. a height of the sidewall WF layer of the first transistor) is different from a height of the second WF material (i.e. a height of the sidewall WF layer of the second transistor).

Example 2 provides the transistor arrangement according to Example 1, where the first transistor further includes a gate fill material, e.g. a gate fill metal, between the fin of the first transistor and the first WF material (i.e. the sidewall WF layer of the first transistor).

Example 3 provides the transistor arrangement according to Example 2, where the second transistor further includes a gate fill material (which could be the same or different from the gate fill material of the first transistor), e.g. a gate fill metal, between the fin of the second transistor and the second WF material (i.e. the sidewall WF layer of the second transistor), and where, in the direction substantially parallel to the height of the fin of the first or second transistor (i.e. in the direction substantially perpendicular to the base), a height of the gate fill material of the first transistor is different from a height of the gate fill material of the second transistor.

Example 4 provides the transistor arrangement according to Examples 2 or 3, where the height of the gate fill material of the first transistor is greater than the height of the first WF material (i.e. the gate fill material of the first transistor extends farther away from the base than the sidewall WF layer of the first transistor).

Example 5 provides the transistor arrangement according to Examples 2 or 3, where the height of the first WF material is greater than the height of the gate fill material of the first transistor (i.e. the sidewall WF layer of the first transistor extends farther away from the base than the gate fill material of the first transistor).

Example 6 provides the transistor arrangement according to any one of Examples 2-5, where the first transistor further includes the gate fill material above the fin of the first transistor.

Example 7 provides the transistor arrangement according to any one of Examples 2-6, where the first transistor further includes a gate dielectric between the fin of the first transistor and each of the first WF material (i.e. the sidewall WF layer of the first transistor) and the gate fill material of the first transistor.

Example 8 provides the transistor arrangement according to any one of Examples 2-6, where the first WF material of the first transistor is a part of an outer sidewall WF layer of the first transistor, the first transistor further includes the first WF material as a part of an inner sidewall WF layer at least partially enclosing the upper portion of the fin of the first transistor, and at least a portion of the gate fill material of the first transistor is between the inner sidewall WF layer of the first transistor and the outer sidewall WF layer of the first transistor.

Example 9 provides the transistor arrangement according to Example 8, where the inner sidewall WF layer and the outer sidewall WF layer are portions of a single continuous WF layer of the first WF material.

Example 10 provides the transistor arrangement according to Examples 8 or 9, where the first transistor further includes a gate dielectric between the inner sidewall WF layer of the first transistor and the fin of the first transistor.

Example 11 provides the transistor arrangement according to any one of Examples 2-10, where the gate fill material includes tungsten. In a further Example according to any one of Examples 2-11, at least one of the first WF material and the second WF material includes a metal.

Example 12 provides the transistor arrangement according to any one of the preceding Examples, where each of the first transistor and the second transistor is a FinFET.

Example 13 provides the transistor arrangement according to any one of the preceding Examples, where a threshold voltage of the first transistor is different from a threshold voltage of the second transistor.

Example 14 provides the transistor arrangement according to any one of the preceding Examples, a difference in the height of the first WF material and the height of the second WF material is between about 2 and 200 nanometers, e.g. between about 5 and 150 nanometers or between about 10 and 80 nanometers.

In further Examples, the arrangement of the second transistor may be similar to the arrangement of the first transistor in any one of the preceding Examples.

Example 15 provides a method for fabricating a transistor arrangement, the method including forming a plurality of fins, each fin extending away from a base and enclosed by one or more insulating materials (e.g. STI); forming a plurality of openings in a dielectric material surrounding the plurality of fins so that each opening surrounds a different one of the plurality of fins; lining the plurality of openings with a WF material; providing a sacrificial material within at least some of the plurality of openings lined with the WF material so that a height of the sacrificial material within a first opening of the plurality of openings is different from a height of the sacrificial material within a second opening of the plurality of openings; and etching the WF material that is not covered by the sacrificial material.

Example 16 provides the method according to Example 15, where etching the WF material that is not covered by the sacrificial material includes performing a wet etch to remove the WF material that is not covered by the sacrificial material without substantially removing the sacrificial material (i.e. using etchants for which the etching rate of etching the WF material is higher than the etching rate of etching the sacrificial material).

Example 17 provides the method according to Examples 15 or 16, where, after etching the WF material that is not covered by the sacrificial material, the method further includes removing the sacrificial material from the plurality of openings; and depositing a gate fill material, e.g. a metal, within the plurality of openings.

Example 18 provides the method according to Example 17, where depositing the gate fill material includes performing CVD to deposit the gate fill material.

Example 19 provides the method according to Examples 17 or 18, further including etching the WF material and/or the gate fill material so that a height of the WF material within the first opening is different from a height of the WF material within the second opening.

Example 20 provides the method according to Example 19, where etching the WF material and/or the gate fill material includes performing a combination of one or more wet etches and one or more dry etches.

Example 21 provides the method according to any one of Examples 15-20, where lining the plurality of openings with the WF material includes performing ALD to cover exposed surfaces of the plurality of openings with a layer of the WF material.

Example 22 provides the method according to Example 21, where a thickness of the layer of the WF material is between about 2 and 10 nanometers, including all values and ranges therein, e.g. between about 2 and 7 nanometers or between about 4 and 7 nanometers.

Example 23 provides the method according to any one of Examples 15-22, where the WF material includes a metal.

In further Examples, the method according to any one of Examples 15-23 may further include processes for fabricating a transistor arrangement according to any one of the preceding Examples, e.g. any one of Examples 1-14.

Example 24 provides a computing device that includes a substrate and an IC die coupled to the substrate. The IC die includes a transistor arrangement having a plurality of transistors, each transistor including a fin extending away from a base, a gate stack at least partially encompassing an upper portion (the upper-most portion) of the fin, and a WF material over at least a portion of one or more sidewalls of the gate stack, where a height of the WF material (i.e. extent, or dimension, of the WF material measured in a direction substantially perpendicular to the substrate) of a first transistor of the plurality of transistors is different from a height of the WF material of a second transistor of the plurality of transistors.

Example 25 provides the computing device according to Example 24, where the computing device is a wearable or handheld computing device.

Example 26 provides the computing device according to Examples 24 or 25, where the computing device further includes one or more communication chips and an antenna.

Example 27 provides the computing device according to any one of Examples 24-26, where the substrate is a motherboard.

In further Examples, the transistor arrangement of the computing device according to any one of Examples 24-27 may include a transistor arrangement according to any one of Examples 1-14, and/or may be fabricated using a method according to any one of Examples 15-23.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A transistor arrangement, comprising:
a first transistor, including:
a fin, and
a first work function (WF) material at least partially surrounding sidewalls of an upper portion of the fin of the first transistor; and
a second transistor, including:
a fin, and
a second WF material at least partially surrounding sidewalls of an upper portion of the fin of the second transistor,
wherein, in a direction substantially parallel to a height of the fin of the first transistor, a height of the first WF material is different from a height of the second WF material.

2. The transistor arrangement according to claim 1, wherein the first transistor further includes a gate fill material between the fin of the first transistor and the first WF material.

3. The transistor arrangement according to claim 2, wherein the second transistor further includes a gate fill material between the fin of the second transistor and the second WF material, and wherein, in the direction substantially parallel to the height of the fin of the first transistor, a height of the gate fill material of the first transistor is different from a height of the gate fill material of the second transistor.

4. The transistor arrangement according to claim 2, wherein the height of the gate fill material of the first transistor is greater than the height of the first WF material.

5. The transistor arrangement according to claim 2, wherein the height of the first WF material is greater than the height of the gate fill material of the first transistor.

6. The transistor arrangement according to claim 2, wherein the first transistor further includes the gate fill material above the fin of the first transistor.

7. The transistor arrangement according to claim 2, wherein the first transistor further includes a gate dielectric between the fin of the first transistor and each of the first WF material and the gate fill material of the first transistor.

8. The transistor arrangement according to claim 2, wherein:
the first WF material is a part of an outer sidewall WF layer of the first transistor,
the first transistor further includes the first WF material as a part of an inner sidewall WF layer at least partially enclosing the upper portion of the fin of the first transistor, and
at least a portion of the gate fill material of the first transistor is between the inner sidewall WF layer of the first transistor and the outer sidewall WF layer of the first transistor.

9. The transistor arrangement according to claim 8, wherein the inner sidewall WF layer and the outer sidewall WF layer are portions of a single continuous WF layer of the first WF material.

10. The transistor arrangement according to claim 8, wherein the first transistor further includes a gate dielectric between the inner sidewall WF layer of the first transistor and the fin of the first transistor.

11. The transistor arrangement according to claim 2, wherein the gate fill material includes tungsten and wherein at least one of the first WF material and the second WF material includes a metal.

12. The transistor arrangement according to claim 1, wherein each of the first transistor and the second transistor is a field-effect transistor (FinFET).

13. The transistor arrangement according to claim 1, wherein a threshold voltage of the first transistor is different from a threshold voltage of the second transistor.

14. The transistor arrangement according to claim 1, wherein a difference in the height of the first WF material and the height of the second WF material is between about 10 and 80 nanometers.

15. A method for fabricating a transistor arrangement, the method comprising:
forming a plurality of fins, each fin enclosed by one or more insulating materials;
forming a plurality of openings in a dielectric material surrounding the plurality of fins so that each opening surrounds a different one of the plurality of fins;
lining the plurality of openings with a work function (WF) material;
providing a sacrificial material within at least some of the plurality of openings lined with the WF material so that a height of the sacrificial material within a first opening of the plurality of openings is different from a height of the sacrificial material within a second opening of the plurality of openings; and
etching the WF material that is not covered by the sacrificial material.

16. The method according to claim 15, wherein etching the WF material that is not covered by the sacrificial material includes performing a wet etch to remove the WF material that is not covered by the sacrificial material.

17. The method according to claim 15, wherein, after etching the WF material that is not covered by the sacrificial material, the method further includes:
removing the sacrificial material; and
depositing a gate fill material within the plurality of openings.

18. The method according to claim 17, wherein depositing the gate fill material includes performing chemical vapor deposition to deposit the gate fill material.

19. The method according to claim 17, further including:
etching the WF material and/or the gate fill material so that a height of the WF material within the first opening is different from a height of the WF material within the second opening.

20. The method according to claim 19, wherein etching the WF material and/or the gate fill material includes performing a combination of one or more wet etches and one or more dry etches.

21. The method according to claim 15, wherein lining the plurality of openings with the WF material includes performing atomic layer deposition to cover exposed surfaces of the plurality of openings with a layer of the WF material.

22. The method according to claim 21, wherein a thickness of the layer of the WF material is between 2 and 10 nanometers.

23. The method according to claim 15, wherein the WF material includes a metal.

24. A computing device, comprising:
a substrate; and
an integrated circuit (IC) die coupled to the substrate, wherein the IC die includes a transistor arrangement having a plurality of transistors, each transistor including:
a fin extending away from a base,
a gate stack at least partially encompassing an upper portion of the fin, and
a work function (WF) material over at least a portion of one or more sidewalls of the gate stack,
wherein a height of the WF material of a first transistor of the plurality of transistors is different from a height of the WF material of a second transistor of the plurality of transistors.

25. The computing device according to claim 24, wherein the computing device is a wearable or handheld computing device.
